(19) United States
(12) Patent Application Publication
(10) Pub. No.: US 2026/0359697 A1
(43) Pub. Date: Nov. 12, 2026

(54) QUANTUM BIT, QUANTUM COMPUTING DEVICE, AND METHOD FOR MANUFACTURING QUANTUM BIT

(71) Applicant: FUJITSU LIMITED, Kawasaki-shi, Kanagawa (JP)

(72) Inventor: Junichi YAMAGUCHI, Atsugi (JP)

(73) Assignee: FUJITSU LIMITED, Kawasaki-shi, Kanagawa (JP)

(21) Appl. No.: 18/600,107

(22) Filed: Mar. 8, 2024

Related U.S. Application Data
(63) Continuation of application No. PCT/JP2021/034578, filed on Sep. 21, 2021.

(51) Int. Cl. G06N 10/40; G06N 10/20; H10N 50/01; H10N 50/20; H10N 50/85; H10N 60/01; H10N 60/10; H10N 60/80; H10N 60/83; H10N 60/85

(52) U.S. Cl. CPC G06N 10/40; G06N 10/20; H10N 50/01; H10N 50/20; H10N 50/85; H10N 60/83; H10N 60/85; H10N 60/0912; H10N 60/128; H10N 60/805

(57) ABSTRACT

A quantum bit includes: an s-wave superconductor layer; a high-order topological insulator layer provided over the s-wave superconductor layer; a first ferromagnetic insulator layer provided over the higher-order topological insulator layer; and a first gate electrode provided over the first ferromagnetic insulator layer. The high-order topological insulator layer includes: a first region including a first hinge helical channel; and a second region including a second hinge helical channel which is spaced from the first hinge helical channel. The first ferromagnetic insulator layer covers the first hinge helical channel and the second hinge helical channel.

### CROSS-REFERENCE TO RELATED APPLICATION

This application is a continuation application of International Application PCT/JP 2021/034578 filed on Sep. 21, 2021 and designated the U.S., the entire contents of which are incorporated herein by reference.

### FIELD

The embodiment relates to a quantum bit, a quantum computing device, and a method for manufacturing a quantum bit.

### BACKGROUND

Quantum computing devices using Marjoram particles have been studied. As a structure for generating the Marjoram particles, a structure in which a two dimensional topological insulator and an s-wave superconductor are combined has been proposed. As the two dimensional topological insulator, a single-layer film of WTe₂, which is a layered material of a transition-metal dichalcogenide, is used.

Related art is disclosed in Japanese Patent Application Laid-Open No. 2020-96107, U.S. Patent Application Publication No. 2013/0299783, U.S. Patent Application Publication No. 2016/0035674, Japanese Patent Application Laid-Open No. 2013-247267, “N. Read and D. Green, Phys. Rev. B61,10267 (2000)”, “V. Mourik et al., Science 336, 25 (2012)”, “J. Alicea, Rep. Prog. Phys. 75, 076501(2012 )” “S. Wu et al., Science 359, 76 (2018)” and “Y.-B. Choi et al., Nat. Mater 19, 974 (2020).

### SUMMARY

Although proposals have been made based on a theory so far, it is not easy to stably obtain the single-layer film of WTe₂. Therefore, the techniques may not stably express the Marjoram particles.

An object of the present disclosure is to provide a quantum bit, a quantum computing device, and a method for manufacturing the quantum bit, which may stably express a Marjoram particle.

According to an aspect of the embodiments, a quantum bit includes: an s-wave superconductor layer; a high-order topological insulator layer provided over the s-wave superconductor layer; a first ferromagnetic insulator layer provided over the higher-order topological insulator layer; and a first gate electrode provided over the first ferromagnetic insulator layer. The high-order topological insulator layer includes: a first region including a first hinge helical channel; and a second region including a second hinge helical channel which is spaced from the first hinge helical channel. The first ferromagnetic insulator layer covers the first hinge helical channel and the second hinge helical channel.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a top view illustrating a quantum bit according to a first embodiment.

FIG. 2 is a cross-sectional view (part 1) illustrating the quantum bit according to the first embodiment;

FIG. 3 is a cross-sectional view (part 2) illustrating the quantum bit according to the first embodiment.

FIG. 4 is a perspective view illustrating a high-order topological insulator layer.

FIG. 5 is a top view (part 1) illustrating a method for manufacturing the quantum bit according to the first embodiment;

FIG. 6 is a top view (part 2) illustrating the method of manufacturing the quantum bit according to the first embodiment;

FIG. 7 is a top view (part 3) illustrating the method of manufacturing the quantum bit according to the first embodiment;

FIG. 8 is a top view (part 4) illustrating the method of manufacturing the quantum bit according to the first embodiment;

FIG. 9 is a top view (part 5) illustrating the method of manufacturing the quantum bit according to the first embodiment;

FIG. 10 is a top view (part 6) illustrating the method of manufacturing the quantum bit according to the first embodiment;

FIG. 11 is a cross-sectional view (part 1) illustrating the method of manufacturing the quantum bit according to the first embodiment;

FIG. 12 is a cross-sectional view (part 2) illustrating the method of manufacturing the quantum bit according to the first embodiment;

FIG. 13 is a cross-sectional view (part 3) illustrating the method of manufacturing the quantum bit according to the first embodiment;

FIG. 14 is a cross-sectional view (part 4) illustrating the method of manufacturing the quantum bit according to the first embodiment;

FIG. 15 is a cross-sectional view (part 5) illustrating the method of manufacturing the quantum bit according to the first embodiment;

FIG. 16 is a cross-sectional view (part 6) illustrating the method of manufacturing the quantum bit according to the first embodiment;

FIG. 17 is a diagram illustrating a quantum computing device according to a second embodiment.

### DESCRIPTION OF EMBODIMENTS

Hereinafter, embodiments of the present disclosure will be described in detail with reference to the accompanying drawings. Note that in the specification and the drawings, components having substantially the same functional configuration are denoted by the same reference numerals, and, thus, a redundant description thereof may be omitted. In the present disclosure, an X1-X2 direction, a Y1-Y2 direction, and a Z1-Z2 direction are directions orthogonal to each other. A plane including the X1-X2 direction and the Y1-Y2 direction is referred to as an XY plane, a plane including the Y1-Y2 direction and the Z1-Z2 direction is referred to as a YZ plane, and a plane including the Z1-Z2 direction and the X1-X2 direction is referred to as a ZX plane. Note that for the sake of simplicity, the Z1-Z2 direction is defined as a vertical direction, a Z1 side is defined as an upper side, and a Z2 side is defined as a lower side. Further, a planar view means that an object is viewed from the Z1 side, and a planar shape means a shape of the object viewed from the Z1 side.

### First Embodiment

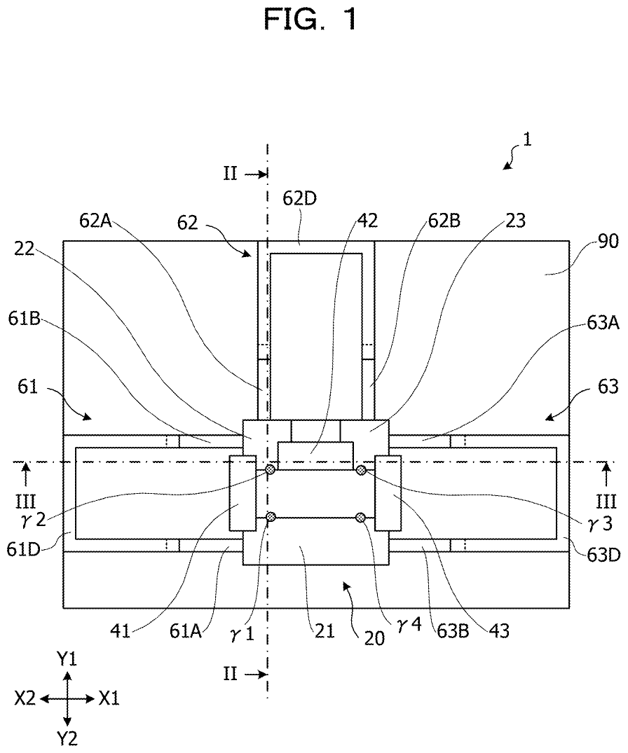

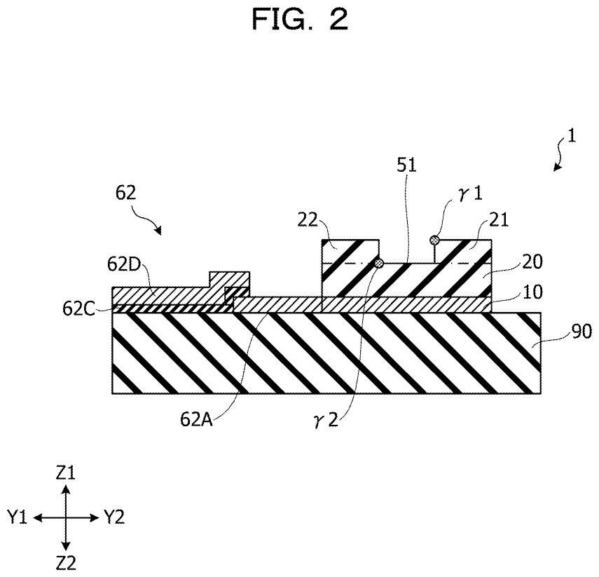

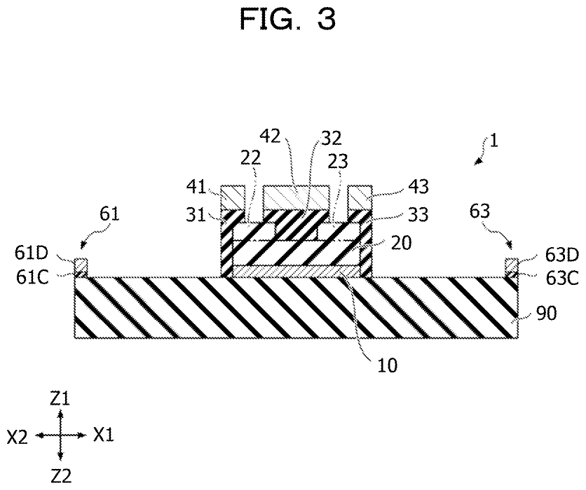

First, a first embodiment will be described. The first embodiment relates to a quantum bit. The quantum bit according to the first embodiment is, for example, used in a quantum computing device such as a quantum computer. FIG. 1 is a top view illustrating the quantum bit according to the first embodiment. FIGS. 2 and 3 are cross-sectional views illustrating the quantum bit according to the first embodiment. FIG. 2 corresponds to a cross-sectional view taken along a line II-II in FIG. 1. FIG. 3 corresponds to a cross-sectional view taken along a line III-III in FIG. 1.

The quantum bit 1 according to the first embodiment includes a substrate 90, an s-wave superconductor layer 10, a high-order topological insulator layer 20, a first ferromagnetic insulator layer 31, a second ferromagnetic insulator layer 32, and a third ferromagnetic insulator layer 33. The quantum bit 1 further includes a first gate electrode 41, a second gate electrode 42, a third gate electrode 43, a first superconducting quantum interference device (SQUID) 61, a second SQUID 62, and a third SQUID 63.

The substrate 90 is, for example, a single crystal substrate having a surface with a Miller index of (100). Examples of the material of the substrate 90 include MgO, mica, sapphire, and SiC.

The s-wave superconductor layer 10 is provided over a part of a surface of the substrate 90. The s-wave superconductor layer 10 is, for example, an Nb layer having a surface with a Miller index of (110). The s-wave superconductor layer 10 is, for example, about 100 nm to 200 nm thick. A planar shape of the s-wave superconductor layer 10 is a rectangle having two sides parallel to the X1-X2 direction and two sides parallel to the Y1-Y2 direction.

The higher-order topological insulator layer 20 is provided over the s-wave superconductor layer 10. The high-order topological insulator layer 20 is, for example, a multilayer WTe₂. For example, the multilayer WTe2 has 5 to 100 layers, preferably 10 to 50 layers, of WTe2 which is a two dimensional material. Since the WTe 2 of a single layer is 0. 7 nm thick, when the higher-order topological insulator layer 20 includes a WTe₂ of 14 layers, the higher-order topological insulator layer 20 is about 10 nm thick.

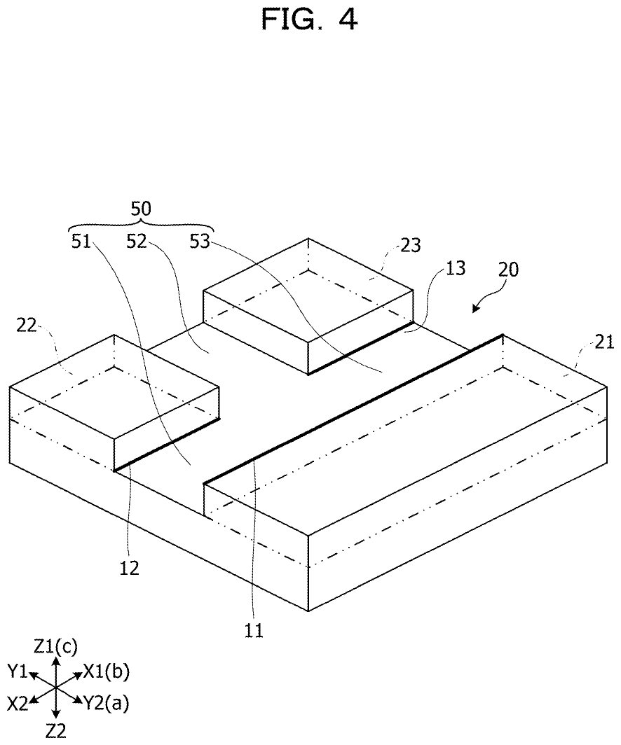

FIG. 4 is a perspective view illustrating the high-order topological insulator layer 20. The shape of the high-order topological insulator layer 20 is substantially a rectangular parallelepiped. An a-axis direction of the high-order topological insulator layer 20 is parallel to the Y1-Y2 direction, a b-axis direction is parallel to the X1-X2 direction, and a c-axis direction is parallel to the Z1-Z2 direction. The mirror index of an upper surface of the high-order topological insulator layer 20 is (001), the mirror index of a side surface on a Y2 side is (100), and the mirror index of a side surface on a X2 side is (010).

A groove 50 having a T-shape in a plan view is formed in a surface of the high-order topological insulator layer 20. The groove 50 includes a first groove 51, a second groove 52, and a third groove 53. For example, widths of the first groove 51, the second groove 52, and the third groove 53 are 20 nm, and depths thereof are 5 nm. The first groove 51 and the third groove 53 extend in parallel in the X1-X2 direction, and the second groove 52 extends in parallel in the Y1-Y2 direction. The first groove 51 is provided in the vicinity of a center of the higher-order topological insulator layer 20 in the Y1-Y2 direction, and extends from an end of the higher-order topological insulator layer 20 on the X2 side to the center in the X1-X2 direction. The third groove 53 is provided in the vicinity of the center of the higher order topological insulator layer 20 in the Y1-Y2 direction, and extends from an end of the higher-order topological insulator layer 20 on an X1 side to the center in the X1-X2 direction. Therefore, the first groove 51 and the third groove 53 are formed in a straight line. The second groove 52 is provided in the vicinity of the center of the higher order topological insulator layer 20 in the X1-X2 direction, and extends from an end of the higher-order topological insulator layer 20 on a Y1 side to the center in the Y1-Y2 direction. Therefore, the second groove 52 is orthogonal to the first groove 51 and the third groove 53.

The high-order topological insulator layer 20 has a first region 21 on the Y2 side of the first groove 51 and the third groove 53. The high-order topological insulator layer 20 has a second region 22 on the Y1 side of the first groove 51 and on the X2 side of the second groove 52. The higher-order topological insulator layer 20 has a third region 23 on the Y1 side of the third groove 53 and on the X1 side of the second groove 52.

Each of the first region 21, the second region 22, and the third region 23 includes a hinge helical channel on one of two lines of intersection between a plane perpendicular to the a-axis direction and a plane perpendicular to the c-axis direction. The hinge helical channel is parallel to the b-axis direction. For example, the first region 21 includes a first hinge helical channel 11 at the intersection (ridge) of a side surface on the Y1 side and an upper surface. The second region 22 includes a second hinge helical channel 12 at the intersection of a side surface on the Y2 side and a lower surface of the first groove 51. The third region 23 includes a third hinge helical channel 13 at the intersection of a side surface on the Y2 side surface and a lower surface of the third groove 53. The first hinge helical channel 11 may be located at the intersection of the side surface on the Y1 side of the first region 21 and a lower surface of the groove 50, the second hinge helical channel 12 may be located at the intersection of an upper surface of the second region 22 and the side surface on the Y2 side of the second region 22, and the third hinge helical channel 13 may be located at the intersection of an upper surface of the third region 23 and the side surface on the Y2 side of the third region 23.

The first ferromagnetic insulator layer 31 is provided over the first region 21, the second region 22, and a part of the groove 50, and covers a part of the first hinge helical channel 11 and the second hinge helical channel 12. The second ferromagnetic insulator layer 32 is provided over the second region 22, the third region 23, and a part of the groove 50, and covers a part of the second hinge helical channel 12 and the third hinge helical channel 13. The third ferromagnetic insulator layer 33 is provided over the third region 23, the first region 21, and a part of the groove 50, and covers a part of the third hinge helical channel 13 and the first hinge helical channel 11. The material of the first ferromagnetic insulator layer 31, the second ferromagnetic insulator layer 32, and the third ferromagnetic insulator layer 33 may be Cr₂Ga₂Te₆. The material of the first ferromagnetic insulator layer 31, the second ferromagnetic insulator layer 32, and the third ferromagnetic insulator layer 33 may be another diluted magnetic semiconductor. The thicknesses of the first ferromagnetic insulator layer 31, the second ferromagnetic insulator layer 32, and the third ferromagnetic insulator layer 33 are, for example, about 30 nm.

The second ferromagnetic insulator layer 32 is separated from the first ferromagnetic insulator layer 31 toward the X1 side over the second hinge helical channel 12 in the X2-X1 direction. The third ferromagnetic insulator layer 33 is separated from the second ferromagnetic insulator layer 32 toward the X1 side over the third hinge helical channel 13 in the X2-X1 direction. The third ferromagnetic insulator layer 33 is separated from the first ferromagnetic insulator layer 31 toward the X1 side over the first hinge helical channel 11 in the X2-X1 direction.

The first gate electrode 41 is provided over the first ferromagnetic insulator layer 31. The second gate electrode 42 is provided over the second ferromagnetic insulator layer 32. The third gate electrode 43 is provided over the third ferromagnetic insulator layer 33. The material of the first gate electrode 41, the second gate electrode 42, and the third gate electrode 43 may be Au. The thicknesses of the first, second, and third gate electrodes 41, 42, and 43 are, for example, about 100 nm.

The first SQUID 61 includes a lower superconductor layer 61A, a lower superconductor layer 61B, a tunnel barrier layer 61C, and an upper superconductor layer 61D.

The lower superconductor layer 61A and the lower superconductor layer 61B protrude from a side surface of the s-wave superconductor layer 10 on the X2 side toward the X2 side. The lower superconductor layer 61A is closer to the Y2 side than the lower superconductor layer 61B. In a plan view, the lower superconductor layer 61A protrudes from the first region 21 toward the X2 side, and the lower superconductor layer 61B protrudes from the second region 22 toward the X2 side. The lower superconductor layer 61A and the lower superconductor layer 61B are formed integrally with the s-wave superconductor layer 10 from the same material as the s-wave superconductor layer 10. The lower superconductor layer 61A and the lower superconductor layer 61B are coupled to the s-wave superconductor layer 10. The lower superconductor layer 61A and the lower superconductor layer 61B are, for example, Nb layers having a thickness of about 100 nm to 200 nm.

The tunnel barrier layer 61C and the upper superconductor layer 61D have a U-shaped planar shape. The material of the tunnel barrier layer 61C may be NbOx, and the material of the upper superconductor layer 61D may be Nb. The tunnel barrier layer 61C is, for example, about 1 nm to 5 nm thick, and the upper superconductor layer 61D is, for example, about 100 nm to 200 nm thick. One end of the tunnel barrier layer 61C is in contact with the lower superconductor layer 61A, and the other end is in contact with the lower superconductor layer 61B. The upper superconductor layer 61D is provided over the tunnel barrier layer 61C.

The tunnel barrier layer 61C is sandwiched between the lower superconductor layer 61A and the upper superconductor layer 61D, and between the lower superconductor layer 61B and the upper superconductor layer 61D. The first SQUID 61 is constituted by such a Josephson junction. The first SQUID 61 detects a change in magnetic flux between the first hinge helical channel 11 and the second hinge helical channel 12.

The second SQUID 62 includes a lower superconductor layer 62A, a lower superconductor layer 62B, a tunnel barrier layer 62C, and an upper superconductor layer 62D.

The lower superconductor layer 62A and the lower superconductor layer 62B protrude from a side surface of the s-wave superconductor layer 10 on the Y1 side toward the Y1 side. The lower superconductor layer 62A is closer to the X2 side than the lower superconductor layer 62B. In a plan view, the lower superconductor layer 62A protrudes from the second region 22 toward the Y1 side, and the lower superconductor layer 62B protrudes from the third region 23 toward the Y1 side. The lower superconductor layer 62A and the lower superconductor layer 62B are formed integrally with the s-wave superconductor layer 10 from the same material as the s-wave superconductor layer 10. The lower superconductor layer 62A and the lower superconductor layer 62B are coupled to the s-wave superconductor layer 10. The lower superconductor layer 62A and the lower superconductor layer 62B are, for example, Nb layers having a thickness of about 100 nm to 200 nm.

The tunnel barrier layer 62C and the upper superconductor layer 62D have a U-shaped planar shape. The material of the tunnel barrier layer 62C may be NbOx, and the material of the upper superconductor layer 62D may be Nb. The tunnel barrier layer 62C is, for example, about 1 nm to 5 nm thick, and the upper superconductor layer 62D is, for example, about 100 nm to 200 nm thick. One end of the tunnel barrier layer 62C is in contact with the lower superconductor layer 62A, and the other end is in contact with the lower superconductor layer 62B. The upper superconductor layer 62D is provided over the tunnel barrier layer 62C.

The tunnel barrier layer 62C is sandwiched between the lower superconductor layer 62A and the upper superconductor layer 62D, and between the lower superconductor layer 62B and the upper superconductor layer 62C. The second SQUID 62 is constituted by such a Josephson junction. The second SQUID 62 detects a change in magnetic flux between the second hinge helical channel 12 and the third hinge helical channel 13.

The third SQUID 63 includes a lower superconductor layer 63A, a lower superconductor layer 63B, a tunnel barrier layer 63C, and an upper superconductor layer 63D.

The lower superconductor layer 63A and the lower superconductor layer 63B protrude from a side surface of the s-wave superconductor layer 10 on the X1 side toward the X1 side. The lower superconductor layer 63A is closer to the Y1 side than the lower superconductor layer 63B. In a plan view, the lower superconductor layer 63A protrudes from the third region 23 toward the X1 side, and the lower superconductor layer 63B protrudes from the first region 21 toward the X1 side. The lower superconductor layer 63A and the lower superconductor layer 63B are formed integrally with the s-wave superconductor layer 10 from the same material as the s-wave superconductor layer 10. The lower superconductor layer 63A and the lower superconductor layer 63B are coupled to the s-wave superconductor layer 10. The lower superconductor layer 63A and the lower superconductor layer 63B are, for example, Nb layers having a thickness of about 100 nm to 200 nm.

The tunnel barrier layer 63C and the upper superconductor layer 63D have a U-shaped planar shape. The material of the tunnel barrier layer 63C may be NbOx, and the material of the upper superconductor layer 63D may be Nb. The tunnel barrier layer 63C is, for example, about 1 nm to 5 nm thick, and the upper superconductor layer 63D is, for example, about 100 nm to 200 nm thick. One end of the tunnel barrier layer 63C is in contact with the lower superconductor layer 63A, and the other end is in contact with the lower superconductor layer 63B. The upper superconductor layer 63D is provided over the tunnel barrier layer 63C.

The tunnel barrier layer 63C is sandwiched between the lower superconductor layer 63A and the upper superconductor layer 63D, and between the lower superconductor layer 63B and the upper superconductor layer 63D. The third SQUID 63 is constituted by such a Josephson junction. The third SQUID 63 detects a change in magnetic flux between the third hinge helical channel 13 and the first hinge helical channel 11.

In the quantum bit 1 configured as described above, four Marjoram particles γ1, γ2, γ3, and γ4 are generated. For example, the marjoram particle γ1 is stably generated in the vicinity of the first gate electrode 41 of the first hinge helical channel 11, and the marjoram particle γ4 is stably generated in the vicinity of the third gate electrode 43 of the first hinge helical channel 11. Further, for example, the marjoram particles γ2 are stably generated between the first gate electrode 41 and the second gate electrode 42 of the second hinge helical channel 12, and the marjoram particles γ3 are stably generated between the second gate electrode 42 and the third gate electrode 43 of the third hinge helical channel 13. Further, an exchange of the marjoram particles γ1 to γ4 is performed by a change in electrostatic potential caused by an application of a gate voltage to the first gate electrode 41, the second gate electrode 42, and the third gate electrode 43.

For example, in the exchange between the marjoram particles γ1 and γ2, an electric field is applied from the first gate electrode 41, and a minute change in the magnetic flux at the time of the exchange between the marjoram particles γ1 and γ2 is detected by the first SQUID 61 as a minute change in a voltage signal. In the exchange of the marjoram particles γ2 and γ3, an electric field is applied from the second gate electrode 42, and a minute change in the magnetic flux at the time of the exchange of the marjoram particles γ2 and γ3 is detected by the second SQUID 62 as a minute change in the voltage signal. Further, in the exchange of the marjoram particles γ3 and γ4, an electric field is applied from the third gate electrode 43, and a minute change in the magnetic flux at the time of the exchange of the marjoram particles γ3 and γ4 is detected by the third SQUID 63 as a minute change in the voltage signal.

The single-layer film of WTe₂, which is a layered material of the transition-metal dichalcogenide, is easily oxidized, and its properties change when exposed to the atmosphere. It is possible to suppress oxidation by sandwiching the single-layer film of WTe₂ between chemically-stable substances such as hexagonal boron nitride (h-BN) and graphene, but in this case, the manufacturing process of quantum bits becomes complicated. Further, it is also difficult to adjust a size of the single-layer film of WTe₂. In contrast, in the present embodiment, the high-order topological insulator layer 20 such as a multilayer WTe₂ is used, and thus a configuration for suppressing oxidation may not be required. Further, the size of the high-order topological insulator layer 20 may be adjusted more easily than the size of the single-layer film of the WTe₂.

Further, it is also possible to provide a plurality of quantum bits 1 over the substrate 90 to realize a multi-quantum bit, or to mount a semiconductor integrated circuit over the substrate 90. Therefore, according to the present embodiment, research and development for realizing a practical error-tolerant quantum computer can be accelerated.

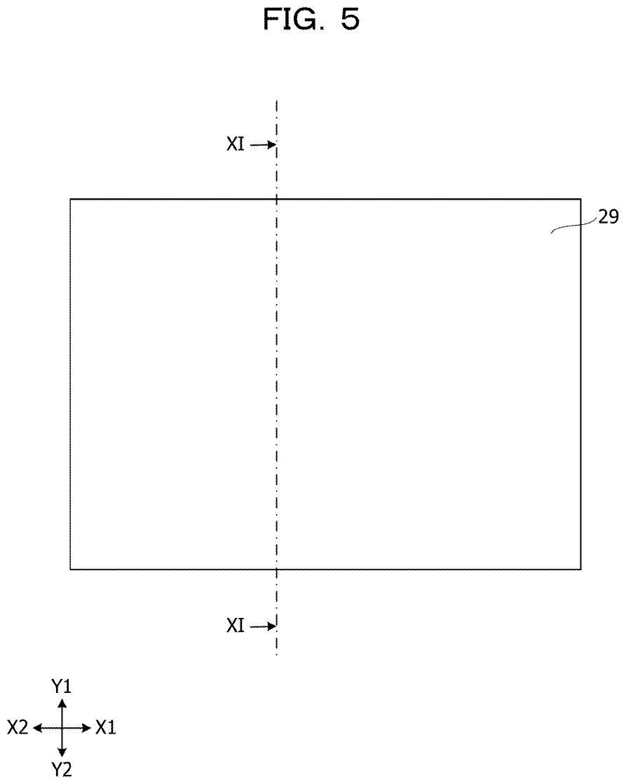

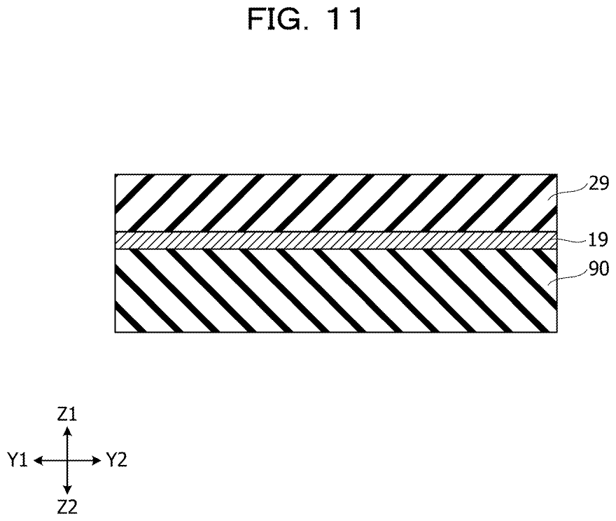

Next, a method of manufacturing the quantum bit 1 according to the first embodiment will be described. FIGS. 5 to 10 are top views illustrating the method for manufacturing the quantum bit 1 according to the first embodiment. FIGS. 11 to 16 are cross-sectional views illustrating the method for manufacturing the quantum bit 1 according to the first embodiment.

First, as illustrated in FIGS. 5 and 11, the substrate 90 is prepared, and the substrate 90 is annealed at about 1200 °C for 3 to 4 hours in an oxygen atmosphere at an atmospheric pressure. Next, the substrate 90 is immersed in methanol for 20 minutes and performed a rinse process with an ultrapure water. By these treatments, a planarity of the surface of the substrate 90 may be improved. FIG. 11 corresponds to a cross-sectional view taken along line XI-XI in FIG. 5.

Thereafter, the s-wave superconductor layer 19 is formed over the substrate 90, and the high-order topological insulator layer 29 is formed over the s-wave superconductor layer 19. In the following description, it is assumed that an Nb layer is formed as the s-wave superconductor layer 19 and a multilayer WTe₂ is formed as the high-order topological insulator layer 29. The s-wave superconductor layer 19 and the high-order topological insulator layer 29 may be epitaxially grown in situ in the same vacuum chamber by, for example, a pulse laser deposition (PLD) method. A basic vacuum degree at the time of forming the s-wave superconductor layer 19 and the high-order topological insulator layer 29 is, for example, 5×10⁻⁶ Pa or less. When the s-wave superconductor layer 19 and the high-order topological insulator layer 29 are formed by the PLD method, a KrF excimer laser (λ=248 nm) source may be used as a laser source. Note that the s-wave superconductor layer 19 and the high-order topological insulator layer 29 may be formed by, for example, a molecular beam epitaxy method, a sputtering method, a co-evaporation method, or the like.

When the Nb layer is formed as the s-wave superconductor layer 19 by the PLD method, for example, a Nb pure metal target may be used as a target. When the s-wave superconductor layer 19 is formed, for example, it is assumed that the temperature of the substrate 90 is maintained at about 400 °C, a laser energy density is 2.0 J/cm² to 5.0 J/cm², an irradiation frequency is 10 Hz, a distance between the substrate 90 and the target is about 5 cm, and a film formation rate is 0.5 nm/min to 1.0 nm/min. The Nb layer is epitaxially grown while being oriented in the [110] direction over the substrate 90 held at about 400 °C.

When the multilayer WTe₂ is formed as the high-order topological insulator layer 29 by the PLD method, for example, a WTe₂ sintered body target may be used as the target. When the high-order topological insulator layer 29 is formed, for example, it is assumed that the temperature of the substrate 90 is maintained at 250 °C to 350 °C, the laser energy density is 1.0 J/cm² to 2.0 J/cm², the irradiation frequency is 1 Hz, the distance between the substrate 90 and the target is about 5 cm, and the film formation rate is 0.1 nm/min to 0.5 nm/min. The high-order topological insulator layer 29 multilayer WTe₂ is oriented in the c-axis direction over the s-wave superconductor layer 19 (Nb layer), and the crystalline structure of the high-order topological insulator layer 29 indicates a T_{d} structure (space group: Pmm2₁).

Note that, after the multilayer WTe₂ is formed, it is preferable to perform post-annealing at about 300 °C for 30 minutes to 1 hour. This is because the crystallinity of the multilayer WTe₂ is improved.

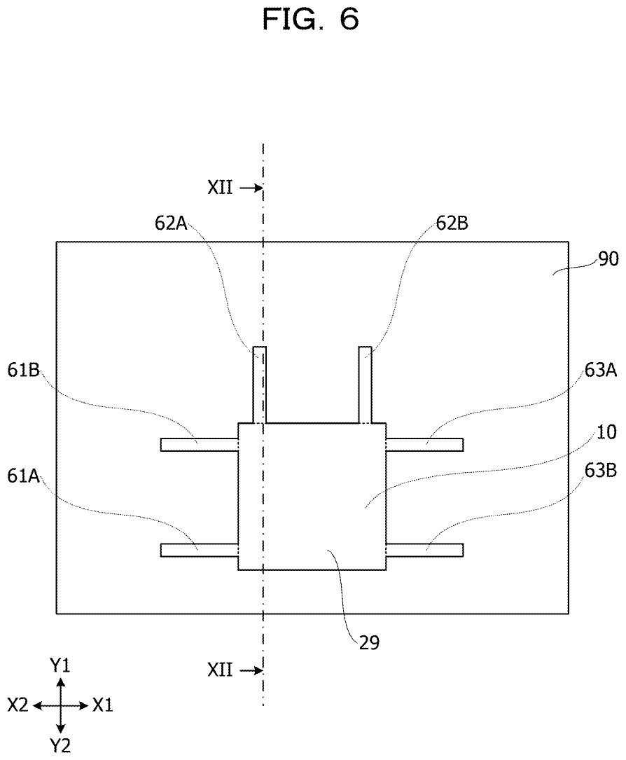

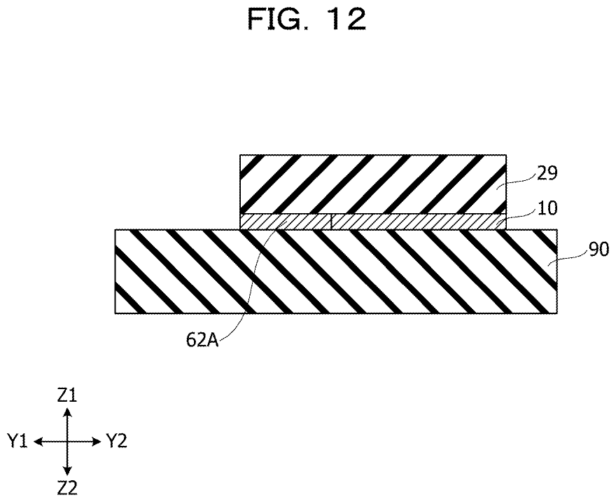

After forming the higher order topological insulator layer 29, as illustrated in FIGS. 6 and 12, the s-wave superconductor layer 19 and the higher order topological insulator layer 29 are processed to form the s-wave superconductor layer 10, the lower superconductor layer 61A, the lower superconductor layer 61B, the lower superconductor layer 62A, the lower superconductor layer 62B, the lower superconductor layer 63A, and the lower superconductor layer 63B from the s-wave superconductor layer 19. FIG. 12 corresponds to a sectional view taken along the line XII-XII in FIG. 6.

When the s-wave superconductor layer 19 and the high-order topological insulator layer 29 are processed, first, a first electron beam resist is spin-coated over the high-order topological insulator layer 29. Next, a first mask pattern is formed from the first electron beam resist by an electron beam lithography. The first mask pattern covers the portions of the s-wave superconductor layer 19 where the s-wave superconductor layer 10, the lower superconductor layer 61A, the lower superconductor layer 61B, the lower superconductor layer 62A, the lower superconductor layer 62B, the lower superconductor layer 63A, and the lower superconductor layer 63B are to be formed, from above the higher-order topological insulator layer 29, and exposes the other portions. As the first electron beam resist, for example, a resist obtained by diluting ZEP 520A (manufactured by Japan Zeon Corporation) with ZEP-A (manufactured by Zeon Corporation) at a ratio of 1:1 may be used. After the first mask pattern is formed, the s-wave superconductor layer 19 and the high-order topological insulator layer 29 are processed by an Ar ion milling. In the Ar ion milling, for example, it is assumed that a beam acceleration voltage is set to 280 V, and a beam current is set to 150 mA.

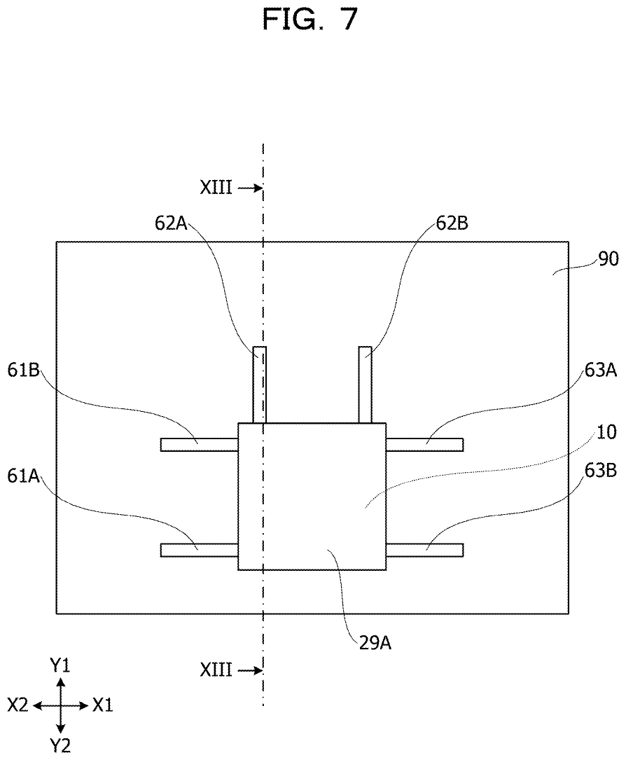

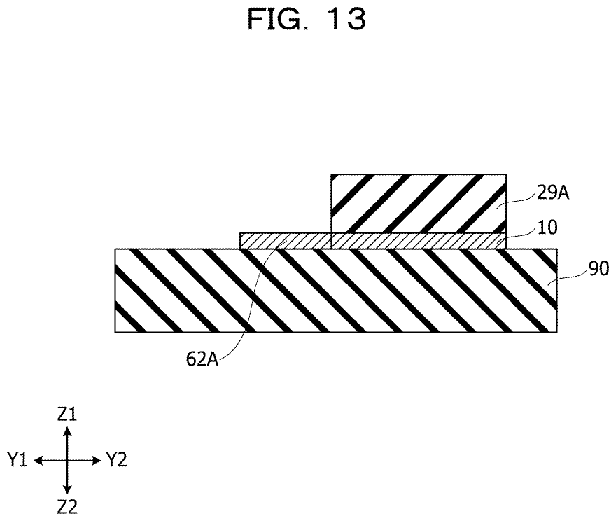

After the s-wave superconductor layer 19 and the high-order topological insulator layer 29 are processed, the first mask pattern is removed, and as illustrated in FIGS. 7 and 13, the high-order topological insulator layer 29 is processed to form a high-order topological insulator layer 29A having a rectangular planar shape and a flat upper surface from the high-order topological insulator layer 29. FIG. 13 corresponds to a cross-sectional view taken along the line XIII-XIII in FIG. 7.

When the high-order topological insulator layer 29 is processed, first, a second electron beam resist is spin-coated over the high-order topological insulator layer 29 and the substrate 90. Then, a second mask pattern is formed from the second electron beam resist by the electron beam lithography. The second mask pattern covers a portion of the higher order topological insulator layer 29 over the s-wave superconductor layer 10 and exposes portions of the higher order topological insulator layer 29 over the lower superconductor layer 61A, the lower superconductor layer 61B, the lower superconductor layer 62A, the lower superconductor layer 62B, the lower superconductor layer 63A, and the lower superconductor layer 63B. As the second electron beam resist, for example, a resist obtained by diluting ZEP 520A (manufactured by Japan Zeon Corporation) with ZEP-A (manufactured by Japan Zeon Corporation) at a ratio of 1:1 may be used. After the second mask pattern is formed, the high-order topological insulator layer 29 is processed by the Ar ion milling. As a result, the higher-order topological insulator layer 29A is formed, and the lower superconductor layer 61A, the lower superconductor layer 61B, the lower superconductor layer 62A, the lower superconductor layer 62B, the lower superconductor layer 63A, and the lower superconductor layer 63B are exposed from the higher-order topological insulator layer 29A. In the Ar ion milling, for example, it is assumed that the beam acceleration voltage is set to 280 V, and the beam current is set to 150 mA.

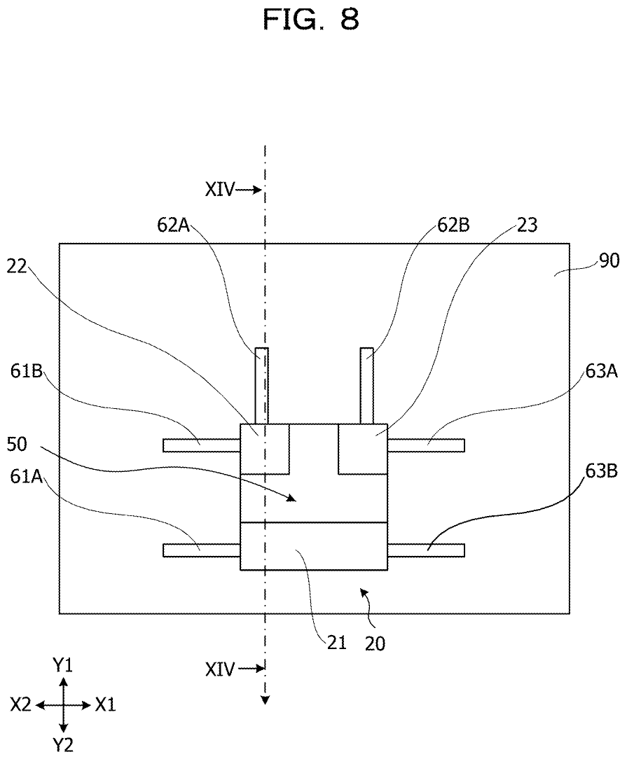

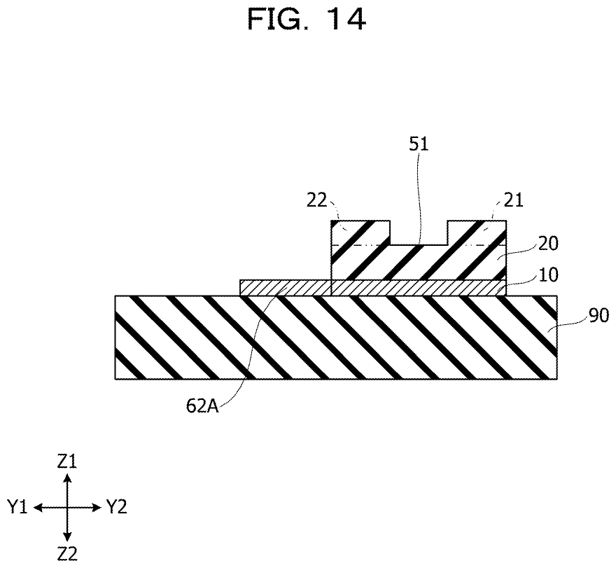

After forming the higher-order topological insulator layer 29A, the second mask pattern is removed, and as illustrated in FIGS. 8 and 14, the higher-order topological insulator layer 29A is processed to form the higher-order topological insulator layer 20 including the first region 21, the second region 22, and the third region 23 from the higher-order topological insulator layer 29A. FIG. 14 corresponds to a cross-sectional view taken along the line XIV-XIV in FIG. 8.

When the higher-order topological insulator layer 29A is processed, first, a third electron beam resist is spin-coated over the higher-order topological insulator layer 29A, the substrate 90, the lower superconductor layer 61A, the lower superconductor layer 61B, the lower superconductor layer 62A, the lower superconductor layer 62B, the lower superconductor layer 63A, and the lower superconductor layer 63B. Then, a third mask pattern is formed from the third electron beam resist by the electron beam lithography. The third mask pattern exposes a portion of the higher-order topological insulator layer 29A where the groove 50 is to be formed, and covers the other portion. As the third electron-beam resist, for example, a resist obtained by diluting ZEP 520A (manufactured by Japan Zeon Corporation) with ZEP-A (manufactured by Japan Zeon Corporation) at a ratio of 1:1 may be used. After the third mask pattern is formed, the high-order topological insulator layer 29A is processed by the Ar ion milling. As a result, the groove 50 including the first groove 51, the second groove 52, and the third groove 53 is formed, and the high-order topological insulator layer 20 including the first region 21, the second region 22, and the third region 23 is obtained. The first region 21 includes the first hinge helical channel 11, the second region 22 includes the second hinge helical channel 12 and the third region 23 includes the third hinge helical channel 13 (see FIG. 4). In the Ar ion milling, for example, it is assumed that the beam acceleration voltage is set to 280 V, and the beam current is set to 150 mA.

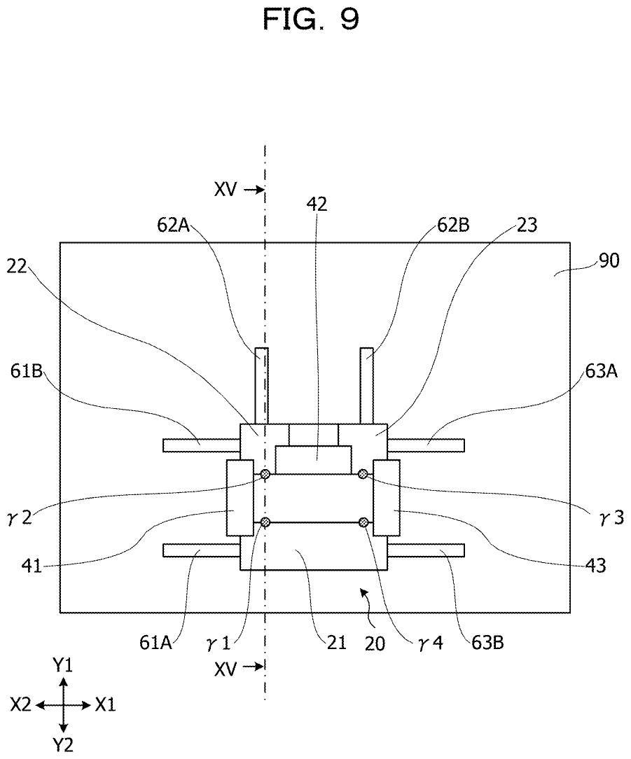

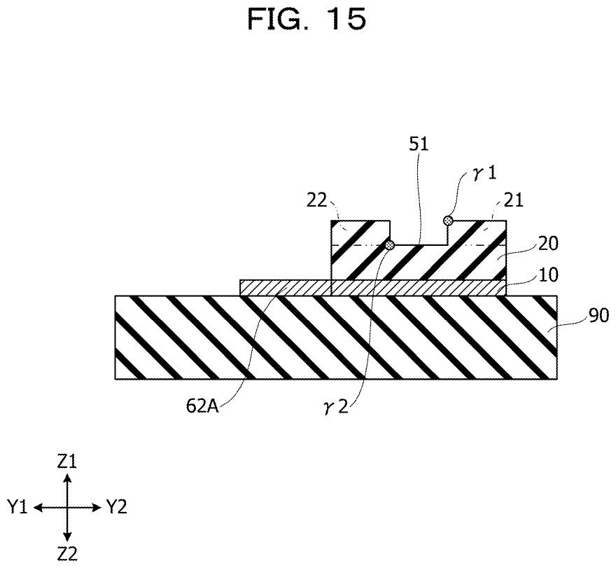

After forming the higher-order topological insulator layer 20, the third mask pattern is removed, and as illustrates in FIGS. 9 and 15, the first ferromagnetic insulator layer 31, the second ferromagnetic insulator layer 32, the third ferromagnetic insulator layer 33, the first gate electrode 41, the second gate electrode 42, and the third gate electrode 43 are formed. FIG. 15 corresponds to a cross-sectional view taken along the line XV-XV in FIG. 9.

When the first, second, and third ferromagnetic insulator layers 31, 32, and 33 and the first, second, and third gate electrodes 41, 42, and 43 are formed, first, a fourth electron beam resist is spin-coated over the higher-order topological insulator layer 20, the substrate 90, the lower superconductor layer 61A, the lower superconductor layer 61B, the lower superconductor layer 62A, the lower superconductor layer 62B, the lower superconductor layer 63A, and the lower superconductor layer 63B. Then, a fourth mask pattern is formed from the fourth electron beam resist by the electron beam lithography. The fourth mask pattern exposes portions where the first ferromagnetic insulator layer 31, the second ferromagnetic insulator layer 32, the third ferromagnetic insulator layer 33, the first gate electrode 41, the second gate electrode 42, and the third gate electrode 43 are to be formed, and covers other portions. As the fourth electron beam resist, for example, a resist obtained by diluting ZEP 520A (manufactured by Japan Zeon Corporation) with ZEP-A (manufactured by Japan Zeon Corporation) at a ratio of 1:1 may be used. After the fourth mask pattern is formed, a Cr₂Ga₂Te₆ layer and an Au layer are formed by the PLD method.

When the Cr₂Ga₂Te₆ layer is formed by the PLD method, for example, it is assumed that the temperature of the substrate 90 is maintained at 150 °C to 250 °C, the laser energy density is 1.0 J/cm² to 2 0 J/cm², the irradiation frequency is 1 Hz, the distance between the substrate 90 and the target is about 5 cm, and the film formation rate is 1.0 nm/min to 2.0 nm/min.

When the Au layer is formed by the PLD method, for example, it is assumed that the temperature of the substrate 90 is maintained at a room temperature, the laser energy density is 1.0 J/cm² to 2.0 J/cm², the irradiation frequency is 5 Hz, the distance between the substrate 90 and the target is about 5 cm, and the film formation rate is 5.0 nm/min to 10.0 nm/min.

After forming the Cr₂Ga₂Te₆ layer and the Au layer, the fourth mask pattern is removed together with the Cr₂Ga₂Te₆ layer and the Au layer deposited thereon. For example, lift-off is performed. As a result, the first ferromagnetic insulator layer 31, the second ferromagnetic insulator layer 32, the third ferromagnetic insulator layer 33, the first gate electrode 41, the second gate electrode 42, and the third gate electrode 43 are obtained. Also, four Marjoram particles γ1, γ2, γ3 and γ4 are expressed.

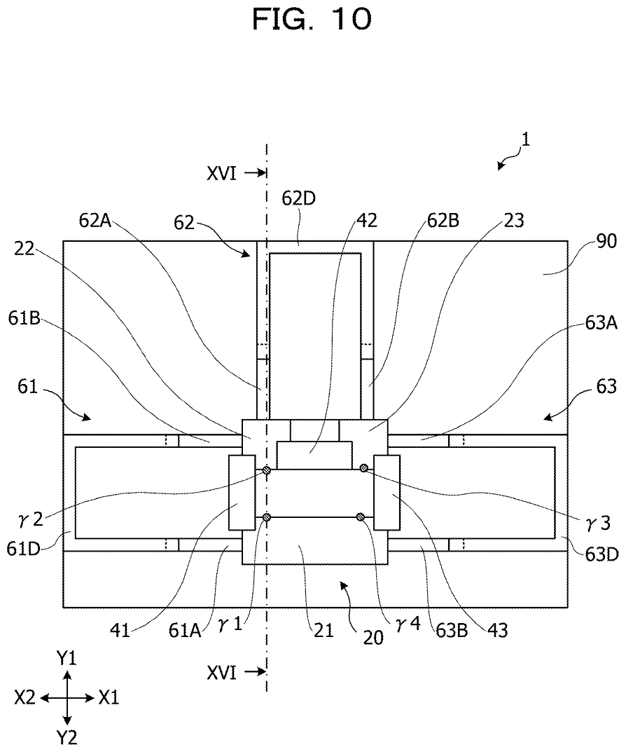

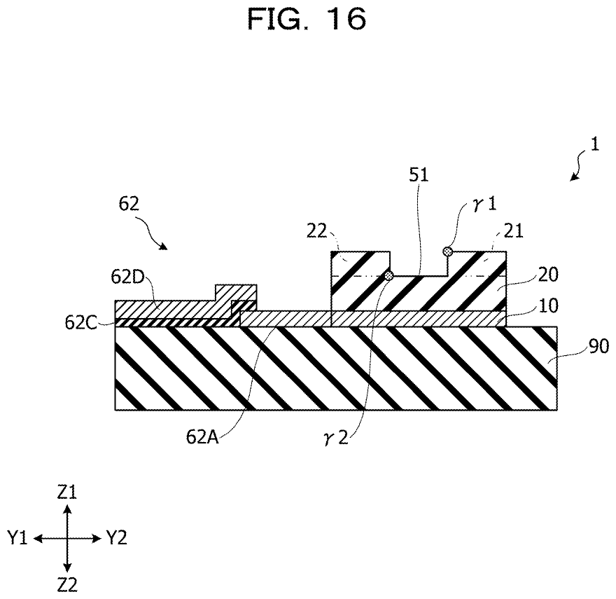

Next, as illustrated in FIGS. 10 and 16, the tunnel barrier layers 61C to 63C and the upper superconductor layers 61D to 63D are formed. FIG. 16 corresponds to a cross-sectional view taken along the line XVI-XVI in FIG. 10.

When the tunnel barrier layers 61C to 63C and the upper superconductor layers 61D to 63D are formed, first, a fifth electron beam resist is spin-coated over the higher-order topological insulator layer 20, the substrate 90, the lower superconductor layer 61A, the lower superconductor layer 61B, the lower superconductor layer 62A, the lower superconductor layer 62B, the lower superconductor layer 63A, the lower superconductor layer 63B, the first gate electrode 41, the second gate electrode 42, and the third gate electrode 43. Next, a fifth mask pattern is formed from the fifth electron beam resist by the electron beam lithography. The fifth mask pattern exposes a portion where the tunnel barrier layers 61C to 63C and the upper superconductor layers 61D to 63D are to be formed, and covers the other portion. As the fifth electron beam resist, for example, a resist obtained by diluting ZEP 520A (manufactured by Japan Zeon Corporation) with ZEP-A (manufactured by Japan Zeon Corporation) at a ratio of 1:1 may be used. After the fifth mask pattern is formed, an NbOx layer and an Nb layer are formed by the PLD method.

When the NbOₓ layer is formed by the PLD method, for example, a Nb metallic target is used, the temperature of the substrate 90 is maintained at the room temperature, and the partial pressure of oxygen in a vacuum tank is adjusted to about 50 Pa to 55 Pa. The Nb layer may be formed under the same condition as the s-wave superconductor layer 19.

After forming the NbOₓ layer and the Nb layer, the fifth mask pattern is removed together with the NbOₓ layer and the Nb layer deposited thereon. For example, the lift-off is performed. As a result, the tunnel barrier layers 61C to 63C and the upper superconductor layers 61D to 63D are obtained, and the first SQUID 61, the second SQUID 62, and the third SQUID 63 are formed.

In this way, the quantum bit 1 according to the first embodiment may be manufactured.

The material of the high-order topological insulator layer 20 is not limited to the multilayer WTe₂, and may be, for example, a multilayer Bi₄ Br₄. Further, the material of the s-wave superconductor layer 10 is not limited to Nb, and may be Al or Pd, for example.

### Second Embodiment

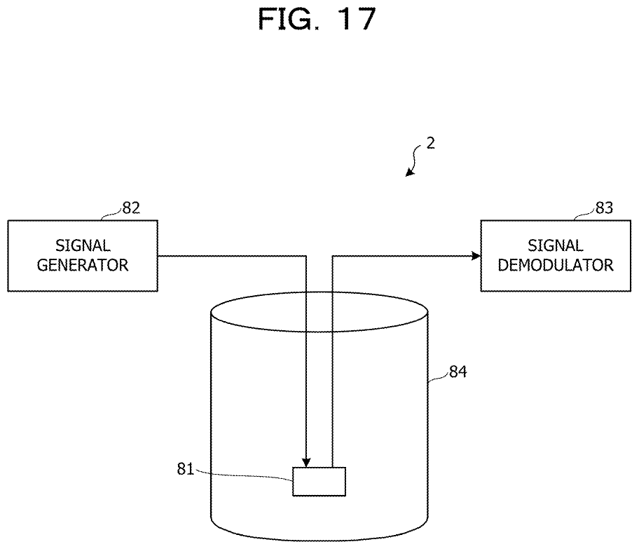

Next, a second embodiment will be described. The second embodiment relates to a quantum computing device including the quantum bit 1 according to the first embodiment. FIG. 17 is a diagram illustrating a quantum computing device according to the second embodiment.

As illustrated in FIG. 17, the quantum computing device 2 according to the second embodiment includes a quantum bit chip 81, a signal generator 82, a signal demodulator 83, and a cryogenic dilution refrigerator 84. The quantum bit chip 81 includes a plurality of quantum bits 1 according to the first embodiment. The quantum bit chip 81 is accommodated in the cryogenic dilution refrigerator 84 and cooled to a temperature equal to or lower than 10 mK. The signal generator 82 generates a microwave pulse signal, and the microwave pulse signal is input to the quantum bit chip 81. The quantum bit chip 81 outputs a signal corresponding to the microwave pulse signal, and the signal demodulator 83 demodulates the signal output from the quantum bit chip 81. The signal generator 82 and the signal demodulator 83 are used at a temperature of, for example, about the room temperature.

Since the quantum computing device 2 according to the second embodiment includes the quantum bit 1 according to the first embodiment, it is possible to stably express the Marjoram particles and to perform stable operation.

Although the preferred embodiments and the like have been described in detail above, the present disclosure is not limited to the above-described embodiments and the like, and various modifications and substitutions may be made to the above-described embodiments and the like without departing from the scope described in the claims.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A quantum bit comprising:
an s-wave superconductor layer;
a high-order topological insulator layer provided over the s-wave superconductor layer;
a first ferromagnetic insulator layer provided over the higher-order topological insulator layer; and
a first gate electrode provided over the first ferromagnetic insulator layer,
wherein the high-order topological insulator layer includes:
a first region including a first hinge helical channel; and
a second region including a second hinge helical channel which is spaced from the first hinge helical channel, and
the first ferromagnetic insulator layer covers the first hinge helical channel and the second hinge helical channel.

2. The quantum bit according to claim 1, further comprising:
a first superconducting quantum interference device configured to detect a change in magnetic flux between the first hinge helical channel and the second hinge helical channel.

3. The quantum bit according to claim 1,
wherein the higher-order topological insulator layer includes a third region with a third hinge helical channel which is spaced from the first hinge helical channel and the second hinge helical channel, and
the quantum bit further includes:
a second ferromagnetic insulator layer which covers the second hinge helical channel and the third hinge helical channel;
a second gate electrode provided over the second ferromagnetic insulator layer;
a third ferromagnetic insulator layer which covers the third hinge helical channel and the first hinge helical channel; and
a third gate electrode provided over the third ferromagnetic insulator layer.

4. The quantum bit according to claim 3, further comprising:
a second superconducting quantum interference device; and
a third superconducting quantum interference device,
wherein the second superconducting quantum interference device is configured to detect a change in magnetic flux between the second hinge helical channel and the third hinge helical channel and the third second superconducting quantum interference device is configured to detect a change in magnetic flux between the third hinged helical channel and the first hinged helical channel.

5. The quantum bit according to claim 3,
wherein the high-order topological insulator layer includes:
a first groove which defines the first region and the second region;
a second groove which defines the second region and the third region; and
a third groove which defines the third region and the first region.

6. The quantum bit according to claim 3,
wherein the first groove and the third groove extend in a first direction, the second groove extends in a second direction perpendicular to the first direction, and
the first groove, the second groove and the third groove are coupled to each other.

7. The quantum bit according to claim 6,
wherein the first groove, the second groove, and the third groove constitute a T-shaped groove in a plan view.

8. The quantum bit according to claim 1,
wherein the higher-order topological insulator layer includes a multilayer WTe₂ or a multilayer Bi₄Br₄.

9. The quantum bit according to claim 1, wherein the s-wave superconductor layer includes Nb, Al or Pd.

10. A quantum computing device comprising the quantum bit according to claim 1.

11. A method of manufacturing a quantum bit comprising:
forming a high-order topological insulator layer over an s-wave superconductor layer;
forming a first ferromagnetic insulator layer over the higher-order topological insulator layer; and
forming a first gate electrode over the first ferromagnetic insulator layer,
wherein the high-order topological insulator layer includes:
a first region including a first hinge helical channel; and
a second region including a second hinge helical channel spaced from the first hinge helical channel,
the first ferromagnetic insulator layer covers the first hinge helical channel and the second hinge helical channel.

12. The method according to claim 11,
wherein the higher-order topological insulator layer includes a third region with a third hinge helical channel which is spaced from the first hinge helical channel and the second hinge helical channel, and
the method further includes:
forming a second ferromagnetic insulator layer which covers the second hinge helical channel and the third hinge helical channel;
forming a third ferromagnetic insulator layer which covers the third hinge helical channel and the first hinge helical channel;
forming a second gate electrode over the second ferromagnetic insulator layer; and
forming a third gate electrode over the third ferromagnetic insulator layer.

13. The method according to claim 12, further comprising:
forming, in the higher-order topological insulator layer, a first groove which defines the first region and the second region, a second groove which defines the second region and the third region, and a third groove which defines the third region and the first region.
